(19) United States
(12) Patent Application Publication
(10) Pub. No.: US 2014/0010995 A1
(43) Pub. Date: Jan. 9, 2014

(54) DEFORMABLE DILATANT TOUCH PANEL SHEET

(71) Applicant: Vincenzo Casasanta, III, Woodinville, WA (US)

(72) Inventor: Vincenzo Casasanta, III, Woodinville, WA (US)

(73) Assignee: EMPIRE TECHNOLOGY DEVELOPMENT LLC, Wilmington, DE (US)

(21) Appl. No.: 13/702,255

(22) PCT Filed: Jul. 5, 2012
(86) PCT No.: PCT/US12/45486

§ 371 Date: Dec. 5, 2012

(51) Int. Cl. H03K 17/96; B05D 5/12; B32B 3/30

(52) U.S. Cl. CPC H03K 17/962; B32B 3/30; B05D 5/12
USPC 428/166; 156/60; 427/80

(57) ABSTRACT

A touch sensitive coating is described. The coating includes a polymer bilayer having a cavity separating the bilayer. The cavity is spanned by a plurality of compartments. A dilatant fluid at least partially fills one or more compartments within the plurality of compartments.

### BACKGROUND

The term “touchscreen” in its most generic form refers to an electronic display device that can detect the presence and location of a touch within the display area. The touch could be by a finger, a hand or a passive object such as a stylus. When attached to an appropriate computing device, a touchscreen makes an intuitive, natural, rapid and accurate interface.

Touchscreens have become the interface of choice for portable computing devices such as smartphones and tablet computers because of their intuitive nature. A touchscreen interface can act as a keyboard and a pointing device, thereby eliminating the need for peripheral computing accessories. Touchscreen interfaces are also popular for game consoles, room automation, kiosks, interactive displays, and so forth.

An effective touch sensor senses the presence and the location the touch. Various technologies can be used as touch sensors. A resistive touchscreen has two thin, transparent electrically resistive layers separated by a thin space and facing each other, one on the underside of the top surface of the screen and one on the top side of the substrate. The layers have conducting connections in orthogonal directions. When an object presses down on the screen surface, the two resistive layers come in contact with each other and act as voltage dividers. By alternatively applying voltage pulses along the two orthogonal directions, the exact location of the touch can be determined Advantages of this technology include low cost and resistance to liquids and contaminants.

Capacitive touchscreens measure change in capacitance when the screen is touched and are based on the fact that the human body is an electrical conductor. Location of the touch may be determined by measuring either a surface capacitance or a projected capacitance. Because they do not have multiple transparent coatings, capacitive touchscreens typically provide better contrast. Variants of capacitive touchscreens may be capable of sensing multiple simultaneous touches.

Other touchscreen technologies include detection of touch location optically using infrared light projections and sensors, mechanical vibrations generated by the touch, or piezoelectricity to sense and locate the position of touch. Optics based technologies are prone to false detection from shadows when, for example, a user hovers their finger above the screen before touching and are, because of their line-of-site nature, limited to flat surfaces. Sensors based on piezoelectricity or mechanical vibration cannot detect resting objects and need complicated algorithms for calculating location of the touch, especially for curved surfaces.

Current touchscreen technologies cannot detect the strength of the touch and, hence, cannot be termed truly touch-sensitive. Thus, current technologies lack an in-built feedback mechanism and need to be coupled with, for example, a haptic or a tactile feedback mechanism for effective user interaction. These technologies, therefore, cannot be used in applications where a control based on strength of touch is required. An example of such an application is a touch-sensitive musical keyboard which may play a note louder if presser harder.

### BRIEF SUMMARY OF THE INVENTION

In an embodiment, a touch-sensitive coating made from a polymer bilayer with a cavity separating the bilayer is described. A plurality of compartments may span the cavity and a dilatant fluid may, at least partially, fill a plurality of compartments.

In an embodiment, a method of manufacturing a touch-sensitive coating is described. A polymer bilayer with a cavity separating the bilayer may be provided wherein, a plurality of compartments may span the cavity and a dilatant fluid may be added, at least partially filling a plurality of compartments.

In an embodiment, a method for applying a touch-sensitive coating to an article of manufacture is described. A deformable sheet of a touch-sensitive coating may be provided wherein the touch-sensitive coating may include a polymer bilayer with a cavity separating the bilayer. A plurality of compartments may span the cavity and a dilatant fluid may, at least partially, fill a plurality of compartments. The deformable sheet may be contacted with the article of manufacture.

In an embodiment, an article of manufacture may have a touch-sensitive coating. The touch-sensitive coating may be made from a polymer bilayer with a cavity separating the bilayer. A plurality of compartments may span the cavity and a dilatant fluid may, at least partially, fill a plurality of compartments.

In an embodiment, a method of using a touch-sensitive coating or an article of manufacture with a touch-sensitive coating is described. The touch-sensitive coating may be made from a polymer bilayer with a cavity separating the bilayer. A plurality of compartments may span the cavity and a dilatant fluid may, at least partially, fill a plurality of compartments. The coating or the article of manufacture may be used by pressing the coating with a digit of a limb or a stylus like device.

### DESCRIPTION OF DRAWINGS

FIG. 1 depicts an illustrative example of a touch-sensitive coating according to an embodiment.

FIG. 2 depicts an illustrative method of manufacturing a touch-sensitive coating according to an embodiment.

FIG. 3 depicts an illustrative method of applying a touch-sensitive coating to an article of manufacture according to an embodiment.

FIG. 4 depicts an illustrative schematic of a touch-sensitive keyboard according to an embodiment.

### DETAILED DESCRIPTION

This disclosure is not limited to the particular systems, devices and methods described, as these may vary. The terminology used in the description is for the purpose of describing the particular versions or embodiments only, and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

One possible approach to obtaining touch-sensitive technology may be found in the form of a dilatant fluid. A dilatant fluid is a material for which viscosity increases with an increase in the rate of shear strain. It is, therefore, also called shear thickening fluid. A dilatant fluid is an example of a non-Newtonian fluid. Examples of dilatant fluids are: (i) mixture of corn-starch with water, and (ii) sand that is completely soaked in water. The parameters that control shear thickening behavior include: particle size and particle size distribution, particle volume fraction, particle shape, particle-particle interaction, continuous phase viscosity, and the type, rate, and time of deformation. Shear thickening fluids are stabilized suspensions and tend to have a high volume fraction of solid.

One application of dilatant fluids is traction control in vehicles. Some all-wheel drive systems use a viscous coupling unit full of dilatant fluid to provide to provide power transfer between front and rear wheels. Under normal operation, there is no relative motion between the primary and secondary drive wheels of the vehicle. But when the primary drive wheels start to slip, the shear between the primary and secondary drive starts increasing, causing the dilatant fluid to thicken. This results in an increase in the torque transferred to the secondary drive wheels that is proportional to the slip, engaging the secondary drive wheels only as much as necessary.

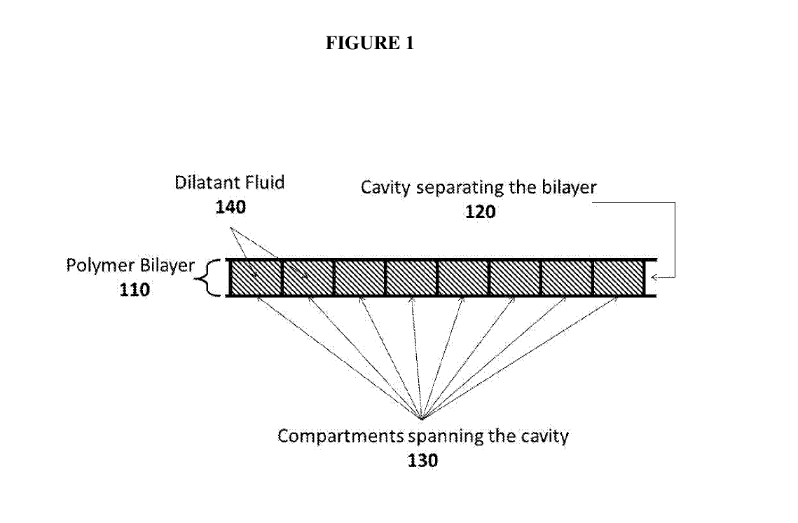

FIG. 1 depicts an illustrative example of a touch-sensitive coating according to an embodiment. The coating may include a polymer bilayer 110 with a cavity 120 separating the bilayer. The cavity 120 may be spanned by a plurality of compartments 130, and a dilatant fluid 140 may, at least partially, fill a plurality of compartments 130.

In some embodiments, the polymer bilayer 110 may comprise a flexible polymer or a flexible co-polymer. Examples of such polymers include, but are not limited to, engineering materials such as polyethylene, polypropylene, poly(ethylene terephthalate), polyvinylchloride, polystyrenes, polyurethanes, polyamides, polyesters, polysiloxanes, and/or the like. Such a flexible bilayer may conform to any shape and form a coating for any arbitrarily shaped device such as, for example, the interior of an automobile, or an electronic appliance. In some embodiments, the polymer bilayer 110 may comprise a transparent polymer or a transparent co-polymer.

The dilatant fluid 140 may be a multiphase colloidal suspension. In general, such a suspension may be: 1) an organic long chain oligomer or polymer residing within a secondary liquid phase so as to form a suspension; or 2) inorganic particles, about 100 nanometer to about 1 micron in size, residing within a secondary liquid phase. Examples, not meant to be exhaustive, include long chain polysaccharides (starches) in aqueous suspension, linear and branched aliphatic polymers or oligomers in alcohol or aqueous/surfactant suspension, inorganic nanoparticles such as silica and alumina in glycol or siloxane suspension, and/or the like. In some embodiments, the dilatant fluid 140 may include a material with average particle size of about 100 nanometer (nm) to about 1 μm, about 200 nm to about 900 nm, about 300 nm to about 800 nm, about 400 nm to about 700 nm, or about 500 nm to about 600 nm In some embodiments, the dilatant fluid 140 comprises a suspension of cornstarch. In some embodiments, the dilatant fluid 140 may include water soluble polymers such as, but not limited to, poly(ethylene glycol), poly(vinyl alcohol), polyethylene oxide, polystyrene sulfonate, dextran(s), starch(es), hydroxylethylcellulose, polyacrylamide, polyacrylic acid, sodium polyacrylate, and/or the like.

In some embodiments, the cavity 120 separating the polymer bilayer may have a thickness of about 25 micrometer (μm) to about 3 millimeter (mm), about 100 μm to about 1 mm, about 200 μm to about 900 μm, about 300 μm to about 800 μm, about 400 μm to about 700 μm, or about 500 μm to about 600 μm. Specific examples of the thickness include about 25 μm, about 50 μm, about 100 μm, about 200 μm, about 300 μm, about 400 μm, about 500 μm, about 600 μm, about 700 μm, about 800 μm, about 900 μm, about 1 mm, and ranges between (and including the endpoints) any two of these values.

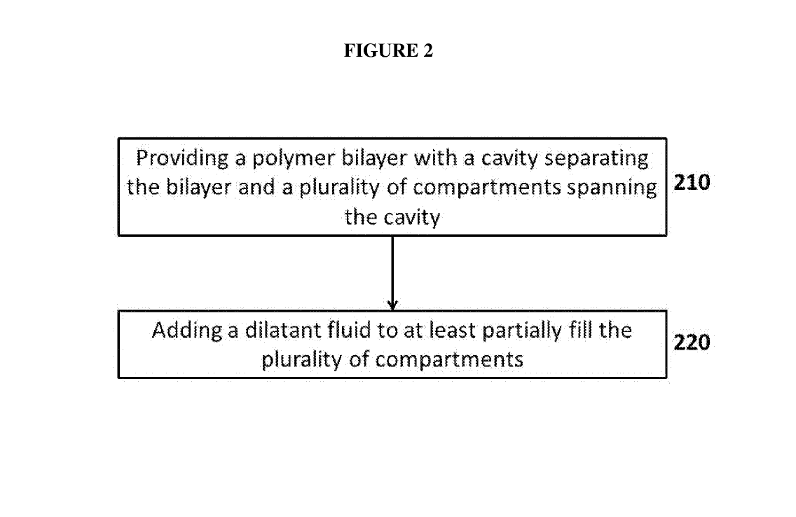

FIG. 2 depicts an illustrative method of manufacturing a touch-sensitive coating according to an embodiment. The method may include providing 210 a polymer bilayer with a cavity separating the bilayer and a plurality of compartments spanning the cavity; and adding 220 a dilatant fluid to at least partially fill a plurality of compartments. In some embodiments, a dilatant fluid is added 220 to at least partially fill a plurality of compartments that span a cavity that separates a polymer bilayer. Various embodiments of the polymer bilayer and the dilatant fluid are described herein.

In general, touchscreen interfaces can be added on to computing devices rather than being integrated within the control system of the devices. Thus, an interface can be converted into a touchscreen interface by adding a touchscreen sensor and a controller-based software. There are a variety of methods for sensing touch such as resistive, surface acoustic wave, capacitive, or dispersive signal sensing, infrared or optical imaging, acoustic pulse recognition, and the like, resulting in a variety of touchscreen technologies, each with its advantages and disadvantages. Common disadvantages of most of these technologies are lack of feedback, and difficulty in applying them for surfaces of arbitrary curvature.

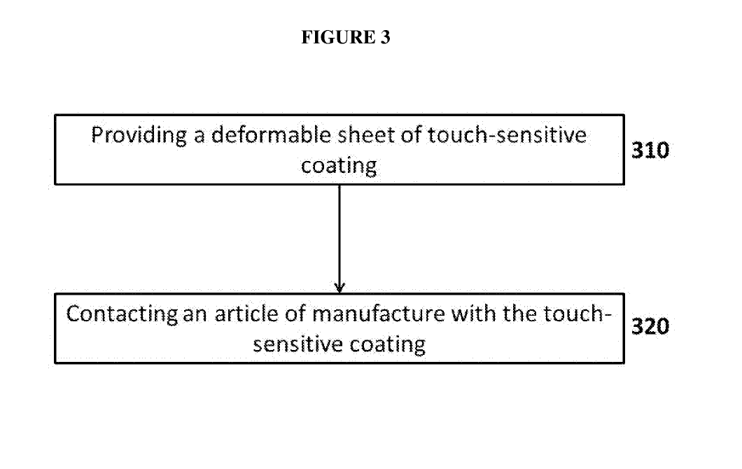

FIG. 3 depicts an illustrative method of applying a touch-sensitive coating to an article of manufacture according to an embodiment. The method may include providing 310 a deformable sheet of touch-sensitive coating, and contacting 320 an article of manufacture with the touch-sensitive coating. The touch-sensitive coating may include a polymer bilayer with a cavity separating the bilayer. The cavity may be spanned by a plurality of compartments, wherein at least one or more of the compartments are filled, at least partially, with a dilatant fluid. In some embodiments, an article of manufacture is contacted 320 with a deformable sheet of touch sensitive coating. Various embodiments of the polymer bilayer and the dilatant fluid are described herein.

In some embodiments, the article of manufacture may be a user interface of, for example, an electronic appliance, an automobile interior, a keyboard, a kiosk, and/or the like. Because the touch-sensitive coating described herein is at least partially filled with a dilatant fluid, the flexibility of the coating depends on the rate at which the coating is contacted with the article of manufacture. When the coating the contacted 320 with the article of manufacture slowly, the dilatant fluid offers low viscosity, and thus, the coating remains flexible. When contacted 320 at a fast rate, the fluid becomes rigid and viscous, thereby making the coating rigid and more difficult to conform to the shape of the article of manufacture.

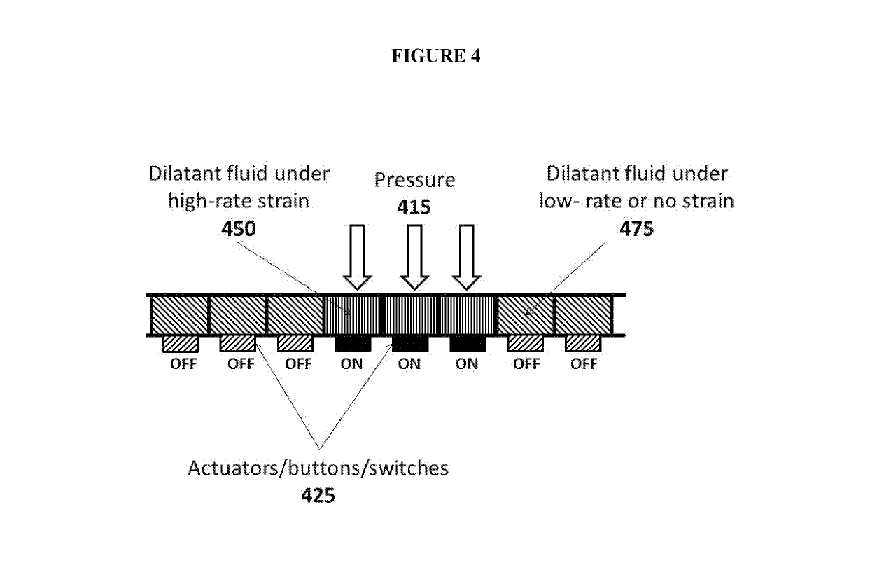

FIG. 4 depicts an illustrative schematic of a touch-sensitive keyboard according to an embodiment. The keyboard may include pressure sensitive actuators/buttons/switches 425 covered by the touch-sensitive coating described herein. When pressure 415 is applied to the touch-sensitive coating, for example, by quickly pressing the touch-sensitive coating by a finger or a stylus-like device, the dilatant fluid inside the compartments to which the pressure 415 is applied becomes rigid 450, thereby activating the actuators/buttons/switches 425 that are present underneath those compartments. The dilatant fluid inside the compartments not affected by the pressure remains pliable 475 and the actuators/buttons/switches 425 are not activated. In some aspects, a method of using a touch-sensitive coating described herein is described. In some embodiments, the method may include pressing the touch-sensitive coating with a digit of a limb. In some embodiments, the limb may be an arm or a leg of an animal. In some embodiments, the animal may be a mammal. In some embodiments, the animal may be a human. In some embodiments, the method may include pressing the touch-sensitive coating with a stylus-like device.

### EXAMPLES

### Example 1

### Manufacturing of a Transparent Touch-Sensitive Coating

A bilayer polyethylene film is used for manufacturing the touch sensitive coating. The thickness of each of the layers is about 5 μm and the gap between the two layers is about 30 μm. The gap between the two layers is filled with a suspension of silica nanoparticles about 100 nm in diameter in ethylene glycol with a ratio of about 1:1 by volume. The suspension acts as a dilatant fluid providing the touch sensitivity to the bilayer film.

The thickness of the polyethylene film may be varied to 10 μm, 20 μm, and so on for alternate embodiments.

For yet other alternate embodiments, the gap between the two layers of the bilayer may be increased to 50 μm, or 100 μm and the dilatant fluid may be replaced by a suspension of corn-starch or other polysaccharides in water.

### Example 2

### Manufacturing a Transparent Touch-Sensitive Coating

A bilayer polystyrene film is blown to create pockets similar to a “bubble wrap”. Each of the pockets has a diameter of about 1 mm and a thickness of about 100 μm and is filled with a dilatant fluid containing an aqueous colloid of polysaccharides. This creates a free-standing touch-sensitive sheet that is laminated on a button panel. The dimensions of the pockets may be suitably changed to suit the particular button panel.

### Example 3

### Using a Touch Sensitive Coating

The touch sensitive coating of example 1 is layered at a slow rate over a an arrangement of buttons or actuators (as seen in FIG. 4). When pressed by a user using a finger or a stylus-like device, the dilatant fluid in the area where the pressure is applied thickens, thereby transferring the force to the button below. The fluid surrounding the area of pressure remains fluid, thereby not transferring any force to the buttons below.

### Example 4

### Using a Touch-Sensitive Coating for Operating a Computing Device

The touch-sensitive coating may be layered over a thin piezo-resistive wire-mesh connected to a processing device. As the force from the coating is transferred to a certain location of on the wire-mesh, the change in resistance of the piezo-resistive elements is allows the processing device to calculate the specific location of the force with respect to the mesh, which may be further used for starting a certain process, as in a touch-sensitive kiosk.

In alternate embodiments, touch sensitive coating, the wire-mesh, and the processing device may be connected electronic equipment such as a computer, a consumer appliance, a smartphone, or a car-stereo. One skilled in the art will readily recognize other devices where the touch-sensitive coating in such an embodiment may be useful.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g.,“a system having at least one of A, B, and C′” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g.,“a system having at least one of A, B, or C′” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. A touch-sensitive coating comprising:
a polymer bilayer, wherein the bilayer is separated by a cavity;
a plurality of compartments spanning the cavity separating the bilayer; and
a dilatant fluid within one or more compartments of the plurality of the compartments.

2. The coating of claim 1, wherein the polymer bilayer comprises a flexible polymer.

3. The coating of claim 1, wherein the polymer bilayer comprises a transparent polymer.

4. The coating of claim 1, wherein the cavity separating the bilayer has a thickness of about 0.5 mm to about 3 mm.

5. The coating of claim 1, wherein the dilatant fluid comprises a suspension of cornstarch in water.

6. The coating of claim 1, wherein the dilatant fluid comprises a material with average particle size of about 100 nm to about 1 μm.

7. The coating of claim 1, wherein the dilatant fluid comprises water-soluble polymers.

8. The coating of claim 7, wherein the water soluble polymer is poly(ethylene glycol) or poly(vinyl alcohol), or a combination thereof.

9. A method of manufacturing a touch-sensitive coating, the method comprising:
adding a dilatant fluid to one or more compartments within a plurality of compartments that span a cavity separating a polymer bilayer of the touch-sensitive coating.

10. The method of claim 9, wherein the polymer bilayer comprises a flexible polymer.

11. The method of claim 9, wherein the polymer bilayer comprises a transparent polymer.

12. The method of claim 9, wherein the wherein the cavity separating the bilayer has a thickness of about 0.5 mm to about 3 mm.

13. The method of claim 9, wherein the dilatant fluid comprises a suspension of cornstarch in water.

14. The method of claim 9, wherein the dilatant fluid comprises a material with an average particle size of about 100 nm to about 1 μm.

15. The method of claim 9, wherein the dilatant fluid comprises water soluble polymers.

16. The method of claim 15, wherein the water soluble polymer is poly(ethylene glycol) or poly(vinyl alcohol), or a combination thereof.

17. A method of applying a touch-sensitive coating to an article of manufacture, the method comprising:
contacting the article of manufacture with a deformable sheet of the touch-sensitive coating,
wherein the coating comprises a polymer bilayer with a cavity separating the bilayer,
wherein a plurality of compartments span the cavity separating the bilayer;
wherein a dilatant fluid at least partially fills one or more compartments within the plurality of the compartments.

18. The method of claim 17, wherein the article of manufacture is a user interface.

19. The method of claim 17, wherein the user interface is a keypad.

20. The method of claim 17, wherein the user interface comprises a surface on the interior of an automobile.

21. The method of claim 17, wherein the user interface comprises a surface of an electronic appliance.

22. An article of manufacture comprising a touch-sensitive coating, wherein the coating comprises:
a polymer bilayer, wherein the bilayer is separated by a cavity;
a plurality of compartments spanning the cavity separating the bilayer; and
a dilatant fluid within one or more compartments within the plurality of the compartments.

23. The article of manufacture of claim 22, wherein the polymer bilayer comprises a flexible polymer.

24. The article of manufacture of claim 22, wherein the polymer bilayer comprises a transparent polymer.

25. The article of manufacture of claim 22, wherein the cavity separating the bilayer has a thickness of about 0.5 mm to about 3 mm.

26. The article of manufacture of claim 22, wherein the dilatant fluid comprises a suspension of cornstarch in water.

27. The article of manufacture of claim 22, wherein the dilatant fluid comprises a material with an average particle size of about 100 nm to about 1 μm.

28. The article of manufacture of claim 22, wherein the dilatant fluid comprises water soluble polymers.

29. The article of manufacture of claim 28, wherein the water soluble polymer is poly(ethylene glycol) or poly(vinyl alcohol), or a combination thereof.

30.-33. (canceled)
